(19) United States
(12) Patent Application Publication
(10) Pub. No.: US 2008/0116793 A1
(43) Pub. Date: May 22, 2008

(54) ORGANIC ELECTROLUMINESCENT DEVICE

(75) Inventors: Chung-Chun Lee, Hsinchu (TW); Hsing-Chuan Li, Hsinchu (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: AU OPTRONICS CORP., Hsinchu (TW)

(21) Appl. No.: 11/757,468

(22) Filed: Jun. 4, 2007

(30) Foreign Application Priority Data
Nov. 21, 2006 (TW) 95142988

(51) Int. Cl. H01L 51/50; H01J 1/62

(52) U.S. Cl. 313/506

(57) ABSTRACT

An organic electroluminescent device. The device comprises a substrate, an anode, an cathode, an electroluminescent structure, and a hole injection layer. The anode and the cathode opposite thereto are disposed on the substrate. The electroluminescent structure is disposed between the anode and the cathode. The hole injection layer is disposed between the anode and the electroluminescent structure and comprises a first sublayer comprising a p-type dopant and a second sublayer not comprising the p-type dopant, in which the first sublayer directly contacts the anode and the second sublayer directly contacts the electroluminescent structure.

### BACKGROUND OF THE INVENTION

1. Field of the Invention

The invention relates to a flat panel display (FPD) device and in particular to an organic light-emitting device (OLED) comprising a hole injection layer with a p-type dopant providing improved device performance.

2. Description of the Related Art

Organic light-emitting diodes (OLEDs) are active lighting devices using organic materials. Compared with conventional inorganic LEDs, OLEDs can be easily fabricated on a large substrate by forming an amorphous silicon layer thereon. Additionally, displays utilizing OLEDs require no backlight module, such that the manufacturing process is simpler and costs are reduced. OLED technology is highly developed and can be employed in small panels such as those in personal digital assistants (PDAs) or digital cameras. As OLED technology matures, application in large panels such as personal computer or television and even flexible display will be possible.

FIG. 2 illustrates a conventional OLED. The OLED 20 comprises a substrate 20, an anode 202, a cathode 214 and an organic electroluminescent layer disposed between the anode 202 and the cathode 214. The electroluminescent layer typically comprises a hole injection layer (HIL) 204 and a hole transport layer (HTL) 206 adjacent to the anode 202, an electron injection layer (EIL) 212 and an electron transport layer (ETL) 210 adjacent to the cathode 214, and a emitting material layer (EML) 208 sandwiched between the HTL 206 and the ETL 210. When an electrical potential difference is applied between the cathode 214 and the anode 202, electrons are injected into the ETL 210 from the cathode 214 through the EIL 212, and then pass through the ETL 210 and the EML 208. At the same time, holes are injected into the HTL 206 from the anode 202 through the HIL 204, and then pass therethrough. The injected electrons and holes are recombined at the interface of the EML 208 and the HTL 206, releasing energy as light.

### BRIEF SUMMARY OF INVENTION

A detailed description is given in the following embodiments with reference to the accompanying drawings. An embodiment of an organic electroluminescent device comprises a substrate, an anode, an cathode, an electroluminescent structure, and a hole injection layer. The anode and the cathode opposite thereto are disposed on the substrate. The electroluminescent structure is disposed between the anode and the cathode. The hole injection layer is disposed between the anode and the electroluminescent structure and comprises a first sublayer comprising a p-type dopant and a second sublayer not comprising the p-type dopant, in which the first sublayer directly contacts the anode and the second sublayer directly contacts the electroluminescent structure.

### BRIEF DESCRIPTION OF DRAWINGS

The invention can be more fully understood by reading the subsequent detailed description and examples with references made to the accompanying drawings, wherein:

FIG. 1 is a cross section of an embodiment of an organic electroluminescent device; and

FIG. 2 is a cross section of a conventional organic electroluminescent device.

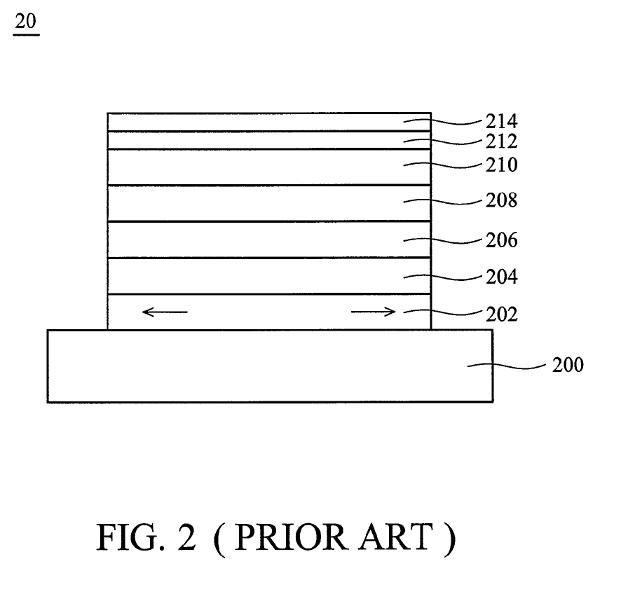

### DETAILED DESCRIPTION OF INVENTION

The following description is of the best-contemplated mode of carrying out the invention. This description is provided for the purpose of illustrating the general principles of the invention and should not be taken in a limiting sense. The scope of the invention is best determined by reference to the appended claims. Embodiments of a semiconductor wafer with an assistant dicing structure and a dicing method thereof are described with reference to the accompanying drawings.

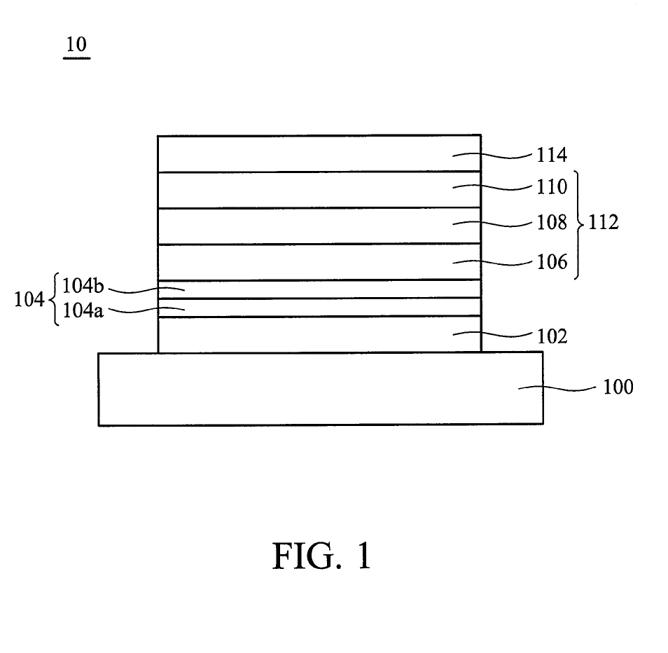

FIG. 1 is a cross section of an embodiment of an organic light-emitting diode (OLED). The OLED 10 comprises a substrate 100, an anode 102, a cathode 114, an electroluminescent structure 112 and a hole injection layer (HIL) 104. The anode 102 and the cathode 114 opposite thereto are disposed on the substrate 100. The electroluminescent structure 112 is disposed between the anode 102 and the cathode 114, in which an electron injection layer (not shown) may be optionally disposed between the cathode 114 and the electroluminescent structure 112. In some embodiments, the cathode 114 may comprise an electron injection layer (EIL).

The HIL 104 is disposed between the anode 102 and the electroluminescent structure 112. In this embodiment, the HIL 104 may comprise a first sublayer 104a and a second sublayer 104b disposed on the first sublayer 104a. The first sublayer 104a has a thickness of about 50 to 5000 Å and the second sublayer 104b has a thickness of about 50 to 5000 Å. In particular, the first sublayer directly contacts the anode 102 and comprises a p-type dopant. The p-type dopant concentration is in a range of about 1% to 20% (volume to volume, v/v). In this embodiment, the p-type dopant may comprise an oxidizing agent (i.e. a compound with high oxidation number) or a compound with strong electro-withdrawing groups. For example, the oxidizing agent may comprise FeCl₃, SbCl₅, WO₃, V₂O₅, MoO₂ or combination thereof. Moreover, the compound with strong electro-withdrawing groups may comprise F₄-TCNQ (tetrafluorotetracyanoquinodimethane) or a derivative thereof or combinations thereof. Additionally, the second sublayer 104b directly contacts the electroluminescent structure 112 and does not comprise the p-type dopant.

The electroluminescent structure 112 comprises a hole transport layer (HTL) 106, an electron transport layer (ETL) 110, and an emitting material layer (EML) 108 disposed therebetween. In this embodiment, the HTL 106 directly contacts the second sublayer 104b and the ETL 110 is disposed adjacent to the cathode 114.

In an embodiment of a fabrication method of the OLED 10, a substrate 100, such as glass or quartz, is provided. An anode 102 is formed on the substrate 100 by deposition for example, such as thermal evaporation, sputtering, or chemical vapor deposition (CVD). The anode 102 may comprise indium oxide (ITO), indium zinc oxide (IZO), aluminum-doped zinc oxide (AZO), zinc oxide (ZnO), or other anode materials known in the art. The substrate 100 with the anode 102 is treated by ultraviolet ozone to decompose organic matter on the substrate 100 and the anode 102.

A first sublayer 104a of an HIL 104 having a thickness of about 50 to 5000 Å and comprising a p-type dopant is formed on the anode 102 by conventional deposition, such as thermal evaporation. In this embodiment, the first sublayer 104a may comprise CuPc, m-MTDATA (4,4′,4″-Tris(N-3-methylphenyl-N-phenyl-amino)-triphenylamine), TPTE (N,N-Bis(4-diphenylaminobiphenyl)-N,N-diphenylbenzidine), NPB (N,N′-diphenyl-N,N′-bis(1-naphthyl)-(1,1′-bisphenyl)-4,4′-diamine). Moreover, the p-type dopant may comprise an oxidizing agent or a compound with strong electro-withdrawing groups and has a dopant concentration of about 1% to 20% (v/v). For example, the oxidizing agent comprises FeCl₃, SbCl₅, WO₃, V₂O₅, MoO₂ or combinations thereof. Thereafter, a second sublayer 104b of the HIL 104 having a thickness of about 50 to 5000 Å not comprising the p-type dopant is formed on the first sublayer by conventional deposition, such as thermal evaporation. In this embodiment, the second sublayer 104b may comprise a material similar as the first sublayer 104a.

An HTL 106, an EML 108 and an ETL 110 are successively formed on the HIL 104 by thermal evaporation for example, to form an electroluminescent structure 112. The HTL 106 may comprise allyl amine, diamine, or a derivative thereof, such as NPB, T-PD (N,N′-diphenyl-N,N′-bis(3-methylphenyl)-(1,1′-bisphenyl)-4,4′-diamine), 1T-NATA (4,4′,4″-tris(N-(1-naphthyl)-N-phenyl-amino)-trisphenyl-amine), or 2T-NATA (4,4′,4″-tris(N-(2-naphthyl)-N-phenyl-amino)-trisphenyl-amine). Moreover, the EML 108 may comprise Alq₃:C545T (Tris(8-hydroxyquinoline)aluminum: 1H,5H,11H-[1]Benzopyrano[6,7,8,-ij]quinolizin-11-one,10-(2-benzothiazolyl)-2,3,6,7-tetrahydro-1,1,7,7,-tetramethyl-(9CI)), MADN:DSA-ph (2-methyl-9,10-di(2-naphthyl)anthracene: p-bis(p-N,N-di-phenyl-aminostyryl)benzene) or other suitable organic material. Additionally, the ETL 110 may comprise Alq₃, aluminum complexes, metal quinolinate, oxadiazole, triazoles or phenanthroline or derivatives thereof.

In some embodiments, the electroluminescent structure 112 can be formed by spin coating, ink jet, or screen printing for example.

Lithium fluoride (LiF) layer and aluminum (Al) layer are successively formed on the electroluminescent structure 112 by thermal evaporation, in which the LiF layer may serve as an EIL and the Al layer may serve as a cathode 114. Thus, the OLED 10 of the embodiment is completed.

According to the embodiment, since the first layer 104a of the HIL 104 comprises a p-type dopant, the highest occupied molecular orbit (HOMO) of the HIL 104 is increased, and energy barrier between the HIL 104 and HTL 106 is lowered, thus the hole injection property is improved and then the operating voltage is reduced. As a result, the lifetime of the device can be extended. Moreover, since the second layer 104b of the HIL 104 does not comprise the p-type dopant, light leakage due to excess dopant concentration in the HIL 104 can be prevented, thereby increasing luminescent efficiency of the device.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organic electroluminescent device, comprising:
a substrate;
an anode and an opposing cathode disposed on the substrate;
an electroluminescent structure disposed between the anode and the cathode; and
a hole injection layer disposed between the anode and the electroluminescent structure and comprising:
a first sublayer directly contacting the anode, comprising a p-type dopant; and
a second sublayer directly contacting the electroluminescent structure not comprising the p-type dopant.

2. The organic electroluminescent device of claim 1, wherein the electroluminescent structure comprises:
a hole transport layer disposed on the second sublayer;
an electron transport layer adjacent to the cathode; and
an emitting material layer disposed between the hole transport layer and the electron transport layer.

3. The organic electroluminescent device of claim 1, further comprising an electron injection layer disposed between the cathode and the electroluminescent structure.

4. The organic electroluminescent device of claim 1, wherein the p-type dopant comprises an oxidizing agent.

5. The organic electroluminescent device of claim 4, wherein the oxidizing agent comprises FeCl₃, SbCl₅, WO₃, V₂O₅, MoO₂ or combinations thereof.

6. The organic electroluminescent device of claim 4, wherein the first sublayer has a thickness of about 50 to 5000 Å.

7. The organic electroluminescent device of claim 6, wherein the second sublayer has a thickness of about 50 to 5000 Å.

8. The organic electroluminescent device of claim 1, wherein the p-type dopant comprises a compound with strong electro-withdrawing groups.

9. The organic electroluminescent device of claim 8, wherein the compound with strong electro-withdrawing groups comprises F₄-TCNQ or a derivative thereof or combinations thereof.

10. The organic electroluminescent device of claim 8, wherein the first sublayer has a thickness of about 50 to 5000 Å.

11. The organic electroluminescent device of claim 10, wherein the second sublayer has a thickness of about 50 to 5000 Å.

12. The organic electroluminescent device of claim 1, wherein the p-type dopant has a dopant concentration of about 1% to 20% (v/v).

13. The organic electroluminescent device of claim 1, wherein the first sublayer has a thickness of about 50 to 5000 Å.

14. The organic electroluminescent device of claim 13, wherein the second sublayer has a thickness of about 50 to 5000 Å.

15. The organic electroluminescent device of claim 1, wherein the second sublayer has a thickness of about 50 to 5000 Å.
